(19) United States
(12) Patent Application Publication
(10) Pub. No.: US 2015/0349726 A1
(43) Pub. Date: Dec. 3, 2015

(54) Mutual Coupling Inductor Based Ultra-Wideband Power Amplifier And Design Method Thereof

(71) Applicant: Wuxi China UniChip Technologies Inc., Wuxi (CN)

(72) Inventors: Kefeng Han, Wuxi (CN); Qiming Ren, Wuxi (CN); Liangjun Lei, Wuxi (CN)

(73) Assignee: Wuxi China UniChip Technologies Inc., Wuxi (CN)

(21) Appl. No.: 14/487,474

(22) Filed: Sep. 16, 2014

(30) Foreign Application Priority Data
May 30, 2014 (CN) 201410239556.6

(51) Int. Cl. H03F 1/42; H03F 3/21; H03F 3/19; G01R 27/02; H03F 1/56

(52) U.S. Cl. CPC H03F 1/42; G01R 27/02; H03F 1/565; H03F 3/19; H03F 3/21; H03F 2200/129; H03F 2200/451; H03F 2200/387

(57) ABSTRACT

A transformer based power amplifier introducing leakage inductance to extend a working bandwidth thereof and corresponding design methodology are provided. An ultra-wideband transformer comprises a primary coil, a secondary coil mutual coupling with the primary coil, a primary tuning capacitor coupled with the primary coil in parallel and a secondary tuning capacitor coupled with the secondary coil in parallel. By means of setting a self-inductance of the primary coil, a self-inductance of the secondary coil, a mutual coupling factor between the primary coil and the secondary coil, a capacitance value of the primary tuning capacitor, and a capacitance value of the secondary tuning capacitor, a 3 dB bandwidth of the transformer covers a first mutual resonated frequency and a second mutual resonated frequency formed by the transformer. This is also applicable to single-stage or transformer coupled multi-stage amplifier design, and to multi-coil coupled implementations, such as transformer-based power combiner power amplifiers.

### CROSS REFERENCE TO RELATED PATENT APPLICATION

The present disclosure claims the priority benefit of China Patent Application No. 201410239556.6, filed on 30 May 2014, which is herein incorporated by reference in its entirety.

### TECHNICAL FIELD

The present disclosure generally relates to RF/microwave amplifier design, and more specifically to wideband amplifier design with mutual coupling inductor based transformer.

### BACKGROUND

At present, wireless mobile communication systems have been used widely. From the 1G analog system in the early 1980s to the 2G digital system in the 1990s, the wireless mobile communication system evolves to a 3G\4 G system at present and may evolve to a 5G system in future. The objective of a wireless communication network is to provide seamless broadband connections to users all around the world.

The wireless mobile communication may be conducted on a plurality of frequency bands. For example, the 2G Global System of Mobile Communications (GSM) standard supports frequency bands of 900 MHz (GSM900), 1800 MHz (GSM1800), and 1900 MHz (GSM1900), and the Wideband Code Division Multiple Access (WCDMA) standard supports up to eight frequency bands. Further, the Long Term Evolution (LTE) standard defines more than 40 frequency bands. Different frequency bands will significantly affect the design of hardware, and in particular, the design of a power amplifier.

Generally, a conventional power amplifier is a narrowband module, and an independent power amplifier needs to be designed for different frequency bands. A multi-mode/multi-frequency-band cellular phone currently comprises a plurality of power amplifiers to support multiple frequency bands. FIG. 1 shows an exemplary block diagram of a traditional multi-mode/multi-frequency-band power amplifier 10, which is capable of supporting n frequency bands, i.e., f1, f2 and fn respectively. The power amplifier 10 comprises an input impedance matching circuit 1, a power amplifier unit 1 and an output impedance matching unit 1, which are designed for the frequency band f1; an input impedance matching circuit 2, a power amplifier unit 2, and an output impedance matching unit 2, which are designed for the frequency band 2; and an input impedance matching circuit n, a power amplifier unit n, and an output impedance matching unit n, which are designed for the frequency band n, wherein n is more than or equal to 2. It can be seen that the independent power amplifier unit and the independent input/output impedance matching network are designed for each frequency band in the current multi-mode/multi-frequency-band power amplifier 10. However, this design results in larger chip area and higher cost.

In the design of radio frequency and microwave circuits, a mutual coupling inductor based transformer (XFMR) is typically adopted to perform input/output impedance matching or stage matching. On one hand, the transformer may be flexibly configured into a differential to differential circuit, and may also be configured into a single-end to single-end circuit, a single end to differential circuit, or a differential to single end circuit. On the other hand, the transformer may provide effective electrostatic discharge (ESD) protection. With respect to an actual circuit, it further has advantages as follows: 1. AC coupling is provided without using any capacitor; 2. the impedance matching design is flexible; and 3. the circuit design further has functions such as power distribution and synthesis. However, in the traditional design, the amplifier circuit based on transformer only has a narrow-band characteristic. In this case, a design method is disclosed to cover broadband frequency for multi-mode/multi-frequency applications, with a plurality of narrowband circuit.

In RF (Radio Frequency) or microwave circuits, such as LNA (Low Noise Amplifier) or PA (Power Amplifier), a RLC network is usually applied. FIG. 2 is a schematic circuit diagram showing a conventional RLC network. Referring to FIG. 2, an inductor L1 provides DC supply voltage for the power amplifier, the output signal swing can be two times of the supply voltage with a DC level of VDD; a capacitor C1 is provided for tuning the LC-tank to wanted frequency band, and a resistor R1 is the load impedance. Sometimes equivalent resistance generated by LC-tank, the bandwidth of RLC network is determined by a quality factor Q. A RLC network is usual for narrow-band use and its input impedance can be express as:

$${Z}_{in} = \frac{{sL}_{1} {R}_{1}}{{s}^{2} {R}_{1} {L}_{1} {C}_{1} + {sL}_{1} + {R}_{1}} \qquad ( 1 )$$

The well-known 3-dB bandwidth Δf1 (namely, in which insertion loss less than 3-dB) can be calculated to be:

$${Df}_{1} = \frac{{f}_{0}}{{Q}_{0}} , \text{?} {f}_{0} = \frac{1}{2 p \sqrt{{L}_{1} {C}_{1}}} , {Q}_{0} = \frac{{R}_{1}}{{w}_{0} {L}_{1}} \\ \text{?} \text{indicates text missing or illegible when filed} \qquad ( 2 )$$

wherein f₀ is a resonated frequency of the RLC network, Q₀ is a quality factor of the RLC network.

FIG. 3A shows an amplitude frequency response of the RLC network shown in FIG. 2.

Mostly, the RLC network can't be used for wideband application except two ways. Firstly, the resonated frequency can be shifted in frequency domain by tuning the capacitance of C1, but the on-chip inductor's quality greatly limit its bandwidth, the derived frequency bandwidth may vary with frequency dramatically, as shown in FIG. 3B, which shows the amplitude frequency response of the RLC network with the tunable capacitor C1. The second way is to lower the R1 or increase the inductance of L1, with a penalty of high loss. Both of the methods are difficult for wideband use.

Recently, a mutual coil coupling transformer is very popular for on-chip PAs, because it can be used for output impedance matching, differential to single-ended conversion (or single-ended to differential conversion conversely), DC supply feeding and ESD protection simultaneously. For some high frequency applications (such as millimeter wave band), the transformers are employed for inter-stage matching. Compared to traditional AC coupled method, the transformer based multi-stage amplifier does not need AC coupled capacitors, and inter-stage impedance matching can be realized directly without any other components, so the layout is becoming much easier compared to traditional AC coupled way.

As shown in FIG. 4, a three stage differential amplifier with a mutual coupling inductor based transformer is provided. T1 is provided for input matching and single to differential conversion, T4 transforms load to an optimal load predicted by load pull simulations, meanwhile, it also performs differential to single ended conversion. T2 and T3 are provided for inter-stage matching, they can also provide supply voltages or bias voltages to circuits if necessary.

FIG. 5 is a schematic circuit of a mutual coupling inductor based transformer. Referring to FIG. 5, for an ideal case, a mutual coupling factor k=1, then the input impedance Zin is:

$${Z}_{in} = \frac{{sL}_{1} {R}_{1}}{{s}^{2} {R}_{1} ( {L}_{1} {C}_{1} + {L}_{2} {C}_{2} ) + {sL}_{2} + {R}_{1}} \qquad ( 3 )$$

wherein L1 is a self inductance of a primary coil L1, L2 is a self inductance of secondary coil L2, C1 and C2 are resonated capacitors for primary and secondary coils respectively, R1 is the load.

To minimize an insertion loss, the resonated frequency f₀ for both primary and secondary coils should be kept the same, so the 3-dB bandwidth Δf2 of the transformer shown FIG. 5 is:

$${Df}_{2} = \frac{{f}_{0 }}{2 {Q}_{0}} , \\ \text{?} {f}_{0} = \frac{1}{2 p \sqrt{{L}_{1} {C}_{1}}} = \frac{1}{2 p \sqrt{{L}_{2} {C}_{2 }}} , \\ {Q}_{0} = \frac{{R}_{1}}{{w}_{0} {L}_{2}} \text{?} \\ \text{?} \text{indicates text missing or illegible when filed} \qquad ( 4 )$$

Equation 4 shows no relationship with ratio n of L1 and L2. With Eq. 2 and Eq. 4, it can be found that equivalent QX for XFMR is:

$${Q}_{X} = \frac{\frac{{f}_{0}}{\sqrt{2}}}{{Df}_{2}} = \sqrt{2} {Q}_{0} \qquad ( 5 )$$

It means the bandwidth of the transformer shown in FIG. 5 is halved of the RLC network shown in FIG. 2 if they have the same quality, as shown in FIG. 6, wherein Line-1 in FIG. 6 is the amplitude frequency response of the XFMR, line-2 is the amplitude response of the RLC network.

So towards bandwidth performance, the transformer is inferior to the RLC network, that's why the transformers in amplifier design are still narrow-band, though maximized measures have been taken, its 3 dB bandwidth still has a long way to fulfill the multi-band requirements.

Thus, a transformer based bandwidth extension technique for a power amplifier is desired to overcome the above disadvantages.

### SUMMARY

This section is for the purpose of summarizing some aspects of the present disclosure and to briefly introduce some preferred embodiments. Simplifications or omissions in this section as well as in the abstract or the title of this description may be made to avoid obscuring the purpose of this section, the abstract and the title. Such simplifications or omissions are not intended to limit the scope of the present disclosure.

In general, the present disclosure is related to a mutual coupling inductor based ultra-wideband power amplifier and a design method thereof. According to one aspect of the present disclosure, an ultra-wideband power amplifier provided in the present disclosure comprises a power amplifier unit configured to amplify a radio frequency input signal; an ultra-wideband impedance matching circuit coupled to an output terminal and/or an input terminal of the power amplifier unit and comprising a primary coil, a secondary coil mutual coupling with the primary coil, a primary tuning capacitor coupled with the primary coil in parallel and a secondary tuning capacitor coupled with the secondary coil in parallel. By means of setting a self-inductance of the primary coil, a self-inductance of the secondary coil, a mutual coupling factor between the primary coil and the secondary coil, a capacitance value of the primary tuning capacitor, and a capacitance value of the secondary tuning capacitor, a 3 dB bandwidth of the impedance matching circuit covers a first mutual resonated frequency and a second mutual resonated frequency formed by the impedance matching circuit.

According to one aspect of the present disclosure, a method for designing an ultra-wideband impedance matching circuit for a power amplifier. The impedance matching circuit comprises a primary coil L1, a secondary coil L2 mutual coupling with the primary coil L1, a primary tuning capacitor C1 coupled with the primary coil in parallel and a secondary tuning capacitor C2 coupled with the secondary coil in parallel. The impedance matching circuit has a first mutual resonated frequency f1 and a second mutual resonated frequency f2. The method comprises: setting a load R1, a desired bandwidth with a lower working frequency fL and a higher working frequency fH, an impedance transformation ratio n of the impedance matching circuit; obtaining a group of configuration parameters according to the load R1, the lower working frequency fL and the higher working frequency fH, the impedance transformation ratio n, wherein the group of configuration parameters comprises a self-inductance of the primary coil L1, a self-inductance of the secondary coil L2, a mutual coupling factor k, a capacitance of the primary tuning capacitor C1 and a capacitance of the secondary tuning capacitor C2; providing a current temporary impedance matching circuit configured with the obtained group of configuration parameters; testing the current temporary impedance matching circuit to get a frequency response characteristic of the current temporary impedance matching circuit; determining whether or not the frequency response characteristic of the current temporary impedance matching circuit meets a design requirement; regarding the current temporary impedance matching circuit as a final temporary impedance matching circuit if the frequency response characteristic of the current temporary impedance matching circuit meets a design requirement; tuning one or more of the self-inductance of the primary coil L1, the self-inductance of the secondary coil L2, the mutual coupling factor k, the capacitance of the primary tuning capacitor C1 and the capacitance of the secondary tuning capacitor C2 to obtain a new group of configuration parameters, and repeating forgoing operations based on the new group of configuration parameters if the frequency response characteristic of the temporary impedance matching circuit doesn't meet the design requirement.

In one embodiment, the obtaining the group of configuration parameters according to the load R1, the lower working frequency fL and the higher working frequency fH, the impedance transformation ratio n comprises:

1. calculating a self inductance of the secondary coil L2 according to:

$${L}_{2} » \frac{{f}_{H} - {f}_{L}}{1 + \sqrt{3}} \frac{{R}_{1}}{2 {pf}_{L}^{2}} ;$$

2. calculating a capacitance of the secondary tuning capacitor C2 according to:

$${f}_{0} = \frac{1}{2 p \sqrt{{L}_{1} {C}_{1}}} = \frac{1}{2 p \sqrt{{L}_{2} {C}_{2 }}} , \\ and$$

$${f}_{0} » \frac{{f}_{L}}{\sqrt{2}} ;$$

3. calculating a self inductance of the primary coil L1 according to:

$$n = \frac{{L}_{1}}{{L}_{2}} ;$$

4. calculating a capacitance of the primary tuning capacitor C1 according to:

$${f}_{0} = \frac{1}{2 p \sqrt{{L}_{1} {C}_{1}}} = \frac{1}{2 p \sqrt{{L}_{2} {C}_{2 }}} , \\ and$$

$${f}_{0} » \frac{{f}_{L}}{\sqrt{2}} ;$$

5. calculating a mutual coupling factor k between the primary coil L1 and the secondary coil L1 according to:

$${f}_{2} = \frac{1}{2 p \sqrt{1 - k}} {f}_{0} , \\ {f}_{0} » \frac{{f}_{L}}{\sqrt{2}} , \\ {f}_{2} » {f}_{H} .$$

Other objects, features, and advantages of the present disclosure will become apparent upon examining the following detailed description of an embodiment thereof, taken in conjunction with the attached drawings.

### BRIEF DESCRIPTION OF THE DRAWINGS

These and other features, aspects, and advantages of the present disclosure will become better understood with regard to the following description, appended claims, and accompanying drawings where:

FIG. 1 is a schematic block diagram showing a conventional multi frequency band power amplifier;

FIG. 2 is a schematic circuit diagram showing a conventional RLC network;

FIG. 3A shows a frequency response of the RLC network shown in FIG. 2;

FIG. 3B shows a frequency response of the RLC network with a tunable capacitor C1;

FIG. 4 shows a three stage differential amplifier with a mutual coupling inductor based transformer;

FIG. 5 is a schematic circuit of a mutual coupling inductor based transformer;

FIG. 6 is a schematic diagram showing an impedance amplitude frequency response of a XFMR, and an impedance frequency response of the RLC network;

FIG. 7 is a schematic block diagram showing an ultra-wideband power amplifier according to one embodiment of the present disclosure;

FIG. 8A shows an ideal frequency response of the XFMR;

FIG. 8B shows a real frequency response of the XFMR;

FIG. 9A and 9B shows a leakage inductance Lx between a primary coil and a secondary coil of the XFMR;

FIG. 10A and 10B shows corresponding frequency response curves of the transformer with different coupling factors;

FIG. 11 is a schematic diagram showing an input return loss curve 1 and an insertion loss curve 2 of the transformer of the present disclosure;

FIG. 12 is a schematic flow diagram showing a method for designing an ultra-wideband XFMR according to one embodiment of the present disclosure;

FIG. 13 is a circuit diagram showing a non-limiting self-biased differential to single-ended wideband buffer, with resistance feedback, according to one embodiment of the present disclosure;

FIG. 14 is a circuit diagram showing a non-limiting common-base wideband amplifier based wideband input transformer XFMR T1 and output wideband transformer XFMR T2 according to one embodiment of the present disclosure;

FIG. 15 is a circuit diagram showing a non-limiting band-pass filter with quality factor enhanced circuit according to one embodiment of the present disclosure;

FIG. 16 is a circuit diagram showing a wideband XFMR with a switchable capacitors according to one embodiment of the present disclosure;

FIG. 17 is a diagram showing bandwidth shifting with frequency when trimming the resonating capacitors;

FIG. 18 shows a non-limiting tunable wideband XFMR according to one embodiment of the present disclosure;

FIG. 19 shows the results of S11 and S21 when the switch in FIG. 15 is ON (dashed line) and OFF (solid line); and

FIG. 20 shows an exemplary and non-limiting schematic of 4-way voltage power combiner with wideband XFMR according to one embodiment of the present disclosure.

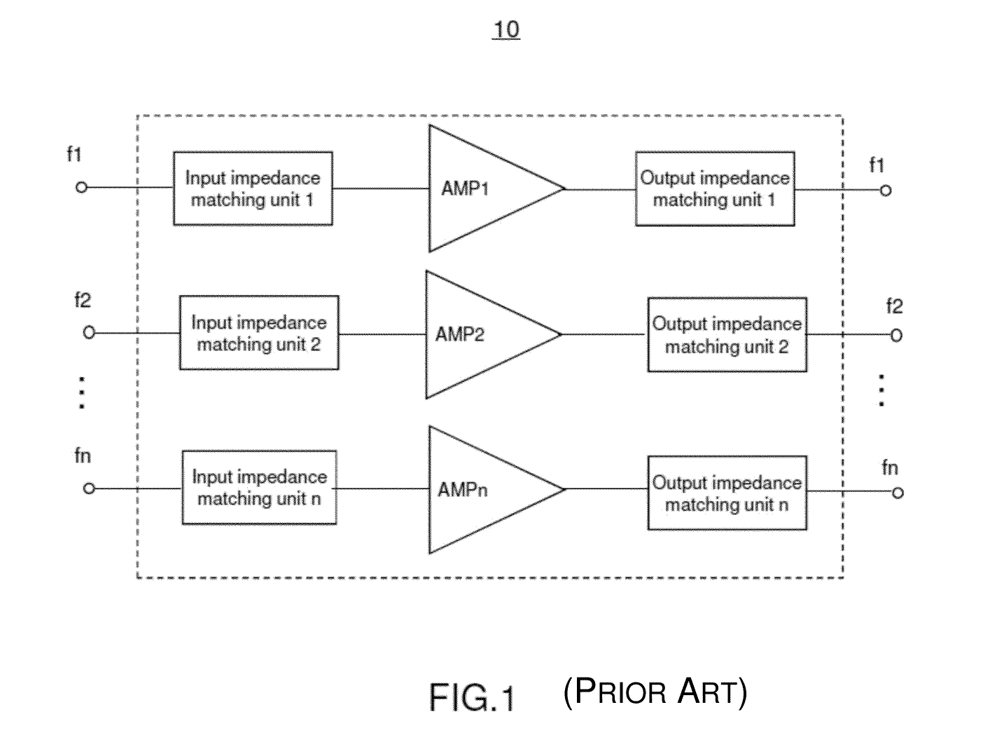

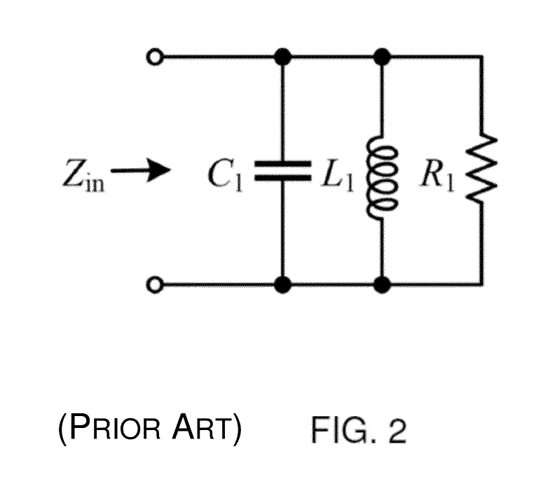

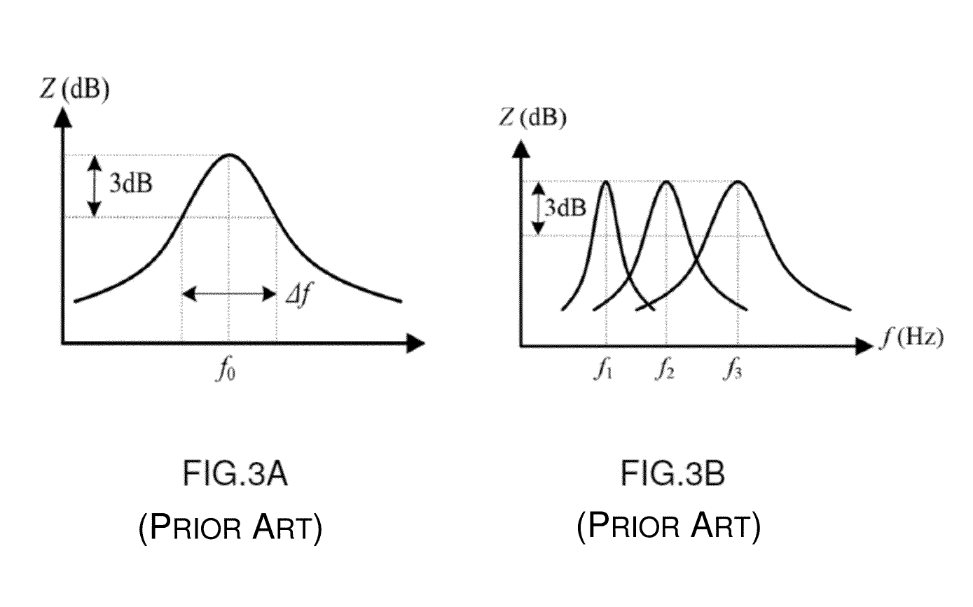

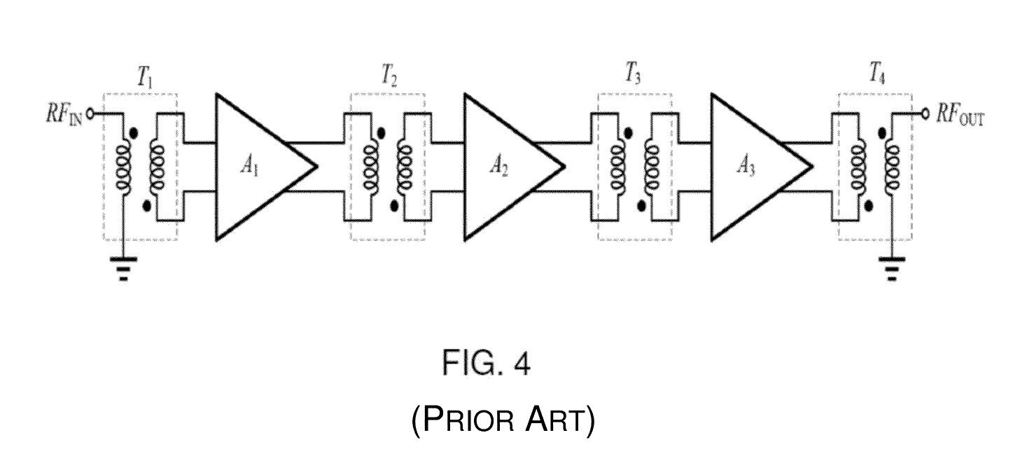

### DETAILED DESCRIPTION OF VARIOUS EMBODIMENTS

The detailed description of the present disclosure is presented largely in terms of procedures, steps, logic blocks, processing, or other symbolic representations that directly or indirectly resemble the operations of devices or systems contemplated in the present disclosure. These descriptions and representations are typically used by those skilled in the art to most effectively convey the substance of their work to others skilled in the art.

Reference herein to “one embodiment” or “an embodiment” means that a particular feature, structure, or characteristic described in connection with the embodiment can be included in at least one embodiment of the present disclosure. The appearances of the phrase “in one embodiment” in various places in the specification are not necessarily all referring to the same embodiment, nor are separate or alternative embodiments mutually exclusive of other embodiments. Further, the order of blocks in process flowcharts or diagrams or the use of sequence numbers representing one or more embodiments of the present disclosure do not inherently indicate any particular order nor imply any limitations in the present disclosure.

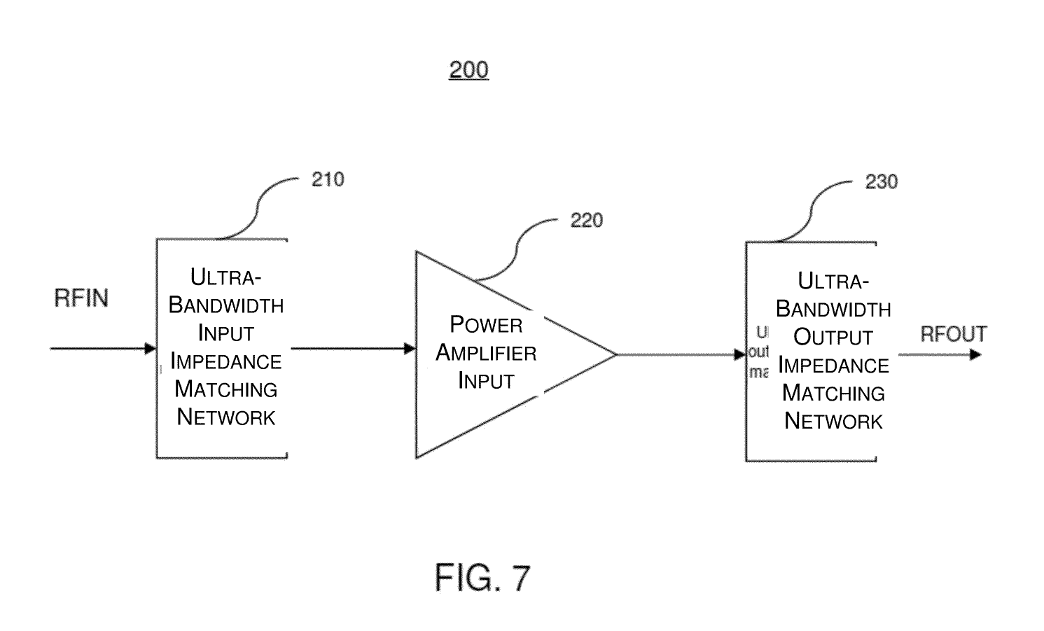

Embodiments of the present disclosure are discussed herein with reference to FIGS. 7-20. However, those skilled in the art will readily appreciate that the detailed description given herein with respect to these figures is for explanatory purposes only as the present disclosure extends beyond these limited embodiments.

FIG. 7 is a schematic block diagram showing an ultra-wideband power amplifier according to an embodiment of the present disclosure. As shown in FIG. 7, the ultra-wideband power amplifier comprises a power amplifier unit 220, an ultra-wideband input impedance matching circuit 210 coupled to an input terminal of the power amplifier unit 220, and an ultra-wideband output impedance matching circuit 230 coupled to an output terminal of the power amplifier unit 220.

The power amplifier unit 220 is configured to amplify a radio frequency input signal RFIN.

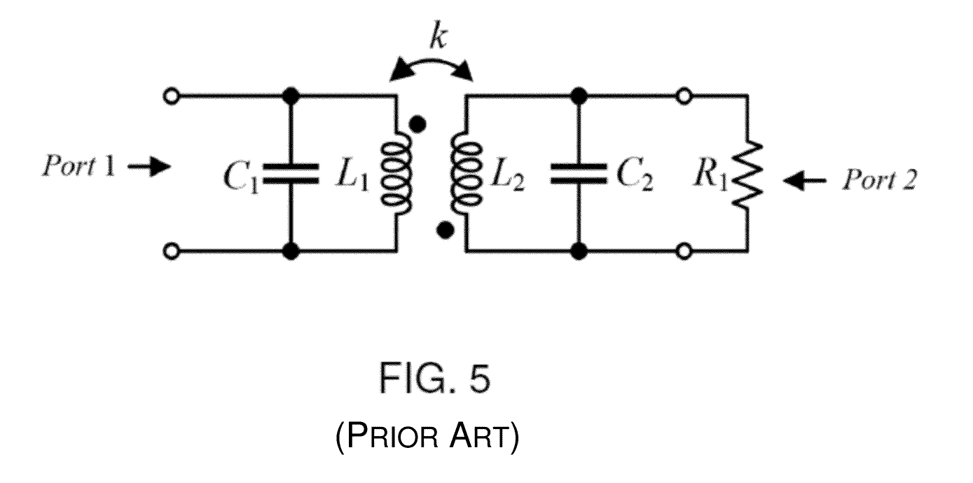

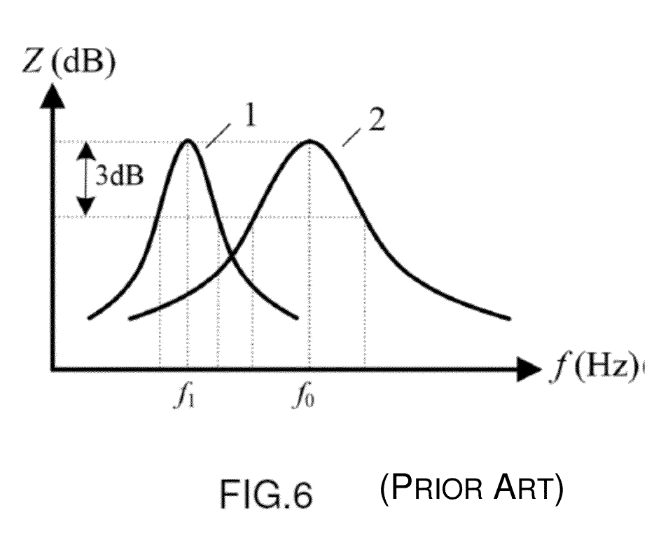

As shown in FIG. 7, the ultra-wideband output impedance matching circuit 210 and/or the ultra-wideband input impedance matching circuit 230 may be a mutual coupling inductor based transformer (XFMR) shown in FIG. 5. The transformer comprises a primary coil L1, a secondary coil L2 mutual coupling with the primary coil L1, a primary tuning capacitor C1 coupled with the primary coil L1 in parallel and a secondary tuning capacitor C2 coupled with the secondary coil L2 in parallel. Two terminals of the primary coil L1 are used to receive the radio frequency signal, and two terminals of the secondary coil L2 are used to output the radio frequency signal.

A mutual coupling factor between the primary coil L1 and the secondary coil L2 is k which is a positive number smaller than 1. By means of configuring a self-inductance of the primary coil, a self-inductance of the secondary coil, the mutual coupling factor between the primary coil and the secondary coil, a capacitance value of the primary tuning capacitor, and a capacitance value of the secondary tuning capacitor, a 3 dB bandwidth of the impedance matching circuit 210 or 230 is able to cover a first mutual resonated frequency and a second mutual resonated frequency formed by the impedance matching circuit 210 or 230.

In one embodiment, a relative bandwidth fBW of the impedance matching circuit 210 or 230 is higher than or equal to 50%, wherein fBW=(fH−fL)/fC, fC=(fH+fL)/2, fL is a minimum working frequency, and fH is a maximum working frequency.

A method to extend the bandwidth of a mutual coupling inductor based transformer is disclosed, and its related design methodology and circuit implementation techniques are also presented. As shown in FIG. 5, without a load R1, an input impedance Zin seen from left of the XFMR is:

$${Z}_{in} = \frac{{s}^{3} {L}_{1} {L}_{2} {C}_{2} ( 1 - {k}^{2} ) + {sL}_{1}}{{s}^{4} {C}_{1} {C}_{2} {L}_{1} {L}_{2} ( 1 - {k}^{2} ) + {s}^{2} ( {L}_{1} {C}_{1} + {L}_{2} {C}_{2} ) + 1} \qquad ( 6 )$$

When the mutual coupling factor k=1, it can be re-written as:

$${Z}_{in} = \frac{{sL}_{1}}{{s}^{2} ( {L}_{1} {C}_{1} + {L}_{2} {C}_{2} ) + 1} \qquad ( 7 )$$

Eq. 8 shows that a pole fi of the XFMR with no leakage inductance and without the load R1:

$${f}_{i} = \frac{1}{2 p \sqrt{{L}_{1} {C}_{1} + {L}_{2} {C}_{2}}} = \frac{{f}_{0}}{\sqrt{2}} , \\ {f}_{0} = \frac{1}{2 p \sqrt{{L}_{1} {C}_{1}}} = \frac{1}{2 p \sqrt{{L}_{2} {C}_{2}}} , \\ i = 1 , 2 , \\ {f}_{1} = {f}_{2} \qquad ( 8 )$$

Here, the resonated frequencies of the primary coil and the secondary coil should be kept the same to ensure a minimum loss for the XFMR. In a real case, the mutual coupling factor k is always smaller than 1, accordingly, poles f1, f2 of Eq. 6 can be given as:

$${f}_{1 , 2}^{2} = \frac{- ( {L}_{1} {C}_{1} + {L}_{2} {C}_{2} ) \pm \sqrt{{( {L}_{1} {C}_{1} + {L}_{2} {C}_{2} )}^{2} - 4 {C}_{1} {C}_{2} {L}_{1} {L}_{2} ( 1 - {k}^{2} )}}{4 {pC}_{1} {C}_{2} {L}_{1} {L}_{2} ( 1 - {k}^{2} )} \qquad ( 9 )$$

With the primary coil and the secondary coil having same resonated frequency f0, the poles of Eq. 9 are calculated to be:

$${f}_{1} = \frac{1}{2 p \sqrt{1 + k}} {f}_{0} , \\ {f}_{2} = \frac{1}{2 p \sqrt{1 - k}} {f}_{0} \qquad ( 10 )$$

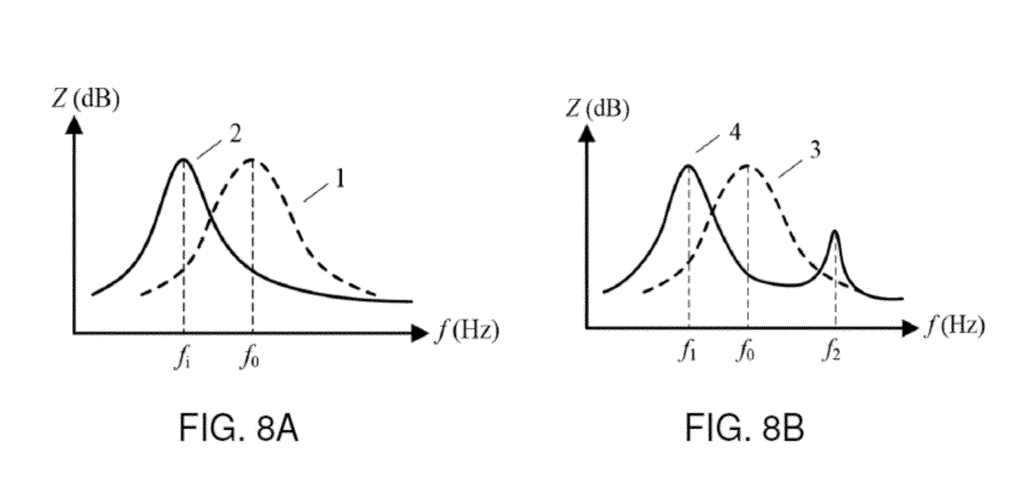

Comparing the results of Eq. 8 and Eq. 10, it can be found that a real XFMR generates two poles versus frequency, for impedance amplitude calculation, the corresponding amplitude frequency response curves are shown in FIGS. 8A and 8B respectively. Line-1 in FIG. 8A is self frequency response both for the primary coil and the secondary coil only, line-2 is the frequency response curve when combined with coupling factor k (k=1), and its quality factor QX is defined in Eq. 5. In FIG. 8B, line-3 is has same definition with line-1 in FIG. 8A, and line-4 is impedance frequency response curve for the real XFMR, besides the lower resonated frequency f1, another resonated frequency f2 appears at higher frequency. This higher frequency peak is generally unwanted, because it does be harm to high frequency characteristics, such as harmonic rejections, noise floors which are critical for modern communication standards, such as GSM, WCDMA, LTE, etc.

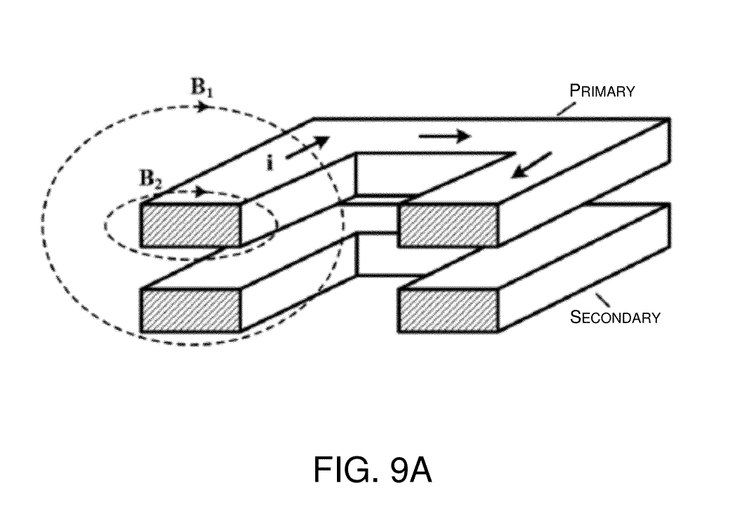

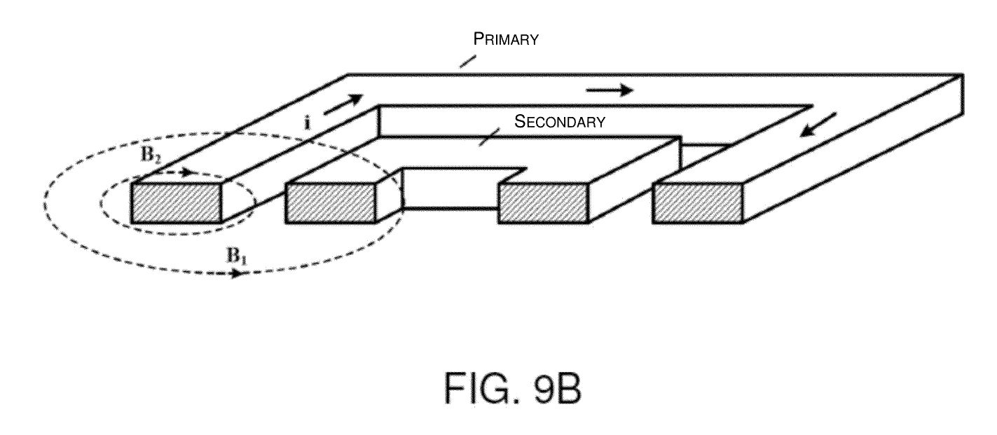

In FIG. 8B, the higher frequency response (Z) peak of f2 comes from a leakage inductance Lx, as shown in FIG. 9A and FIG. 9B. For on-chip or laminate design, a gap between the primary coil and the secondary coil causes missing of magnetic flux to following coils. Take B2 for example, it does not cross over the secondary coil, thus it can only be seen as a part of self-inductance of the primary coil, sometimes it is called leakage inductance.

The total leakage inductance seen from the primary coil can be expressed as:

Lₓ=(1−k²)L₁ (11)

Traditionally, this leakage inductance is ignored and optimization is put on f1, and the impact of the leakage inductance is kept minimized according to Eq. 11, thus a larger k is always preferred for a traditionally way. However, this method greatly lies in the technology used (for a modern CMOS or SiGe technology, the designed coupling factor is generally smaller than 0.8), and its bandwidth is much narrow compared to a RLC network, as predicted in Eq. 4. Besides, from this point of view, a lower k is generally considered a higher loss.

To overcome this disadvantage, a new design methodology that greatly extends the bandwidth of the XFMR is disclosed according to one embodiment of the present disclosure, without sacrifice the insertion loss performance.

In FIG. 5, with the load R1, the impedance Zin seen from left side of the XFMR is:

$${Z}_{i n} = \frac{{s}^{3} {R}_{1} {L}_{1} {L}_{2} {C}_{2} ( 1 - {k}^{2} ) + {s}^{2} {L}_{1} {L}_{2} ( 1 - {k}^{2} ) + {sL}_{1} {R}_{1}}{\begin{matrix}{s}^{4} {R}_{1} {C}_{1} {C}_{2} {L}_{1} {L}_{2} ( 1 - {k}^{2} ) + {s}^{3} {C}_{1} {L}_{1} {L}_{2} ( 1 - {k}^{2} ) + \\ {s}^{2} {R}_{1} ( {L}_{1} {C}_{1} + {L}_{2} {C}_{2} ) + {sL}_{2} + {R}_{1}\end{matrix}} \qquad ( 12 )$$

According to Eq. 9, there are two poles (i.e., resonated frequencies) f1 and f2, at these frequencies if k<1, at such frequencies, the input impedance Z1 can be written as:

$${Z}_{1} = \frac{{L}_{1}}{{L}_{2}} {R}_{1} + \frac{{jwL}_{1} ( 1 - {k}^{2} )}{1 - {w}^{2} {C}_{1} {L}_{1} ( 1 - {k}^{2} )} = \frac{{L}_{1}}{{L}_{2}} {R}_{1} + \frac{{jw}_{0} {L}_{X}}{k \sqrt{1 + k}} \\ {Z}_{2} = \frac{{L}_{1}}{{L}_{2}} {R}_{1} + \frac{{jwL}_{1} ( 1 - {k}^{2} )}{1 - {w}^{2} {C}_{1} {L}_{1} ( 1 - {k}^{2} )} = \frac{{L}_{1}}{{L}_{2}} {R}_{1} - \frac{{jw}_{0} {L}_{X}}{k \sqrt{1 - k}} \qquad ( 13 )$$

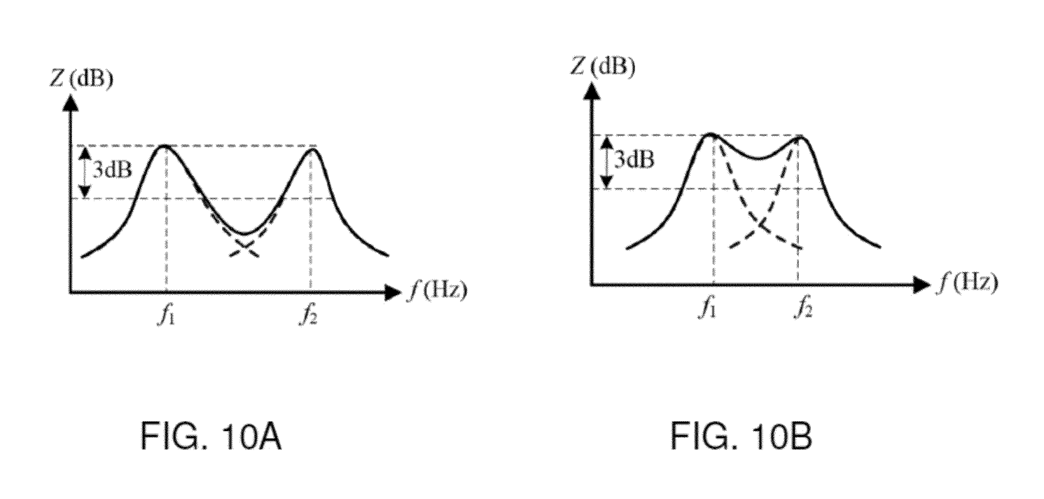

The first terms in Eq. 13 are wanted transformed impedance, proportional to a ratio of L1 and L2, the second terms come from the leakage inductance LX. At both frequencies f1 and f2, the input impedance will be very close to L1R1/L2, so if f2 can be put closer to f1, the overall frequency response will get flat over a wideband of frequency, as illustrated in FIG. 10B.

According to Eq. 5, the quality factor Q1 at f1 is:

$${Q}_{1} = \frac{2 {R}_{1}}{2 {pL}_{2} {f}_{0} \sqrt{1 + k}} = \frac{2 {Q}_{0}}{\sqrt{1 + k}} \qquad ( 14 )$$

The quality factor Q2 at f2 is:

$${Q}_{2} = \frac{2 {R}_{1}}{2 {pL}_{2} {f}_{0} \sqrt{1 - k}} = \frac{2 {Q}_{0}}{\sqrt{1 - k}} \qquad ( 15 )$$

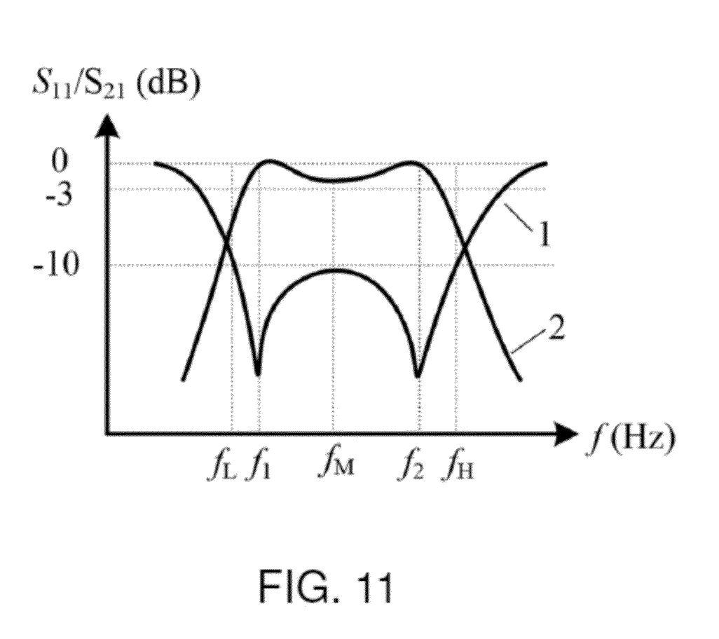

Two metrics must be taken for evaluating the XFMR. The first one is an input return loss (S11), it should be smaller than −10 dB generally. The second one is an insertion loss (S21), it should be less than 3 dB. The former metric is usually tighter than latter one. FIG. 11 is a schematic diagram showing the input return loss curve 1 and the insertion loss curve 2 of the transformer of the present disclosure.

By re-arranging the poles of the transformer in Eq. 12, the S11 of the XFMR has two close notches in frequency, and the S21 of the XFMR has two peaks accordingly, as shown in FIG. 11. The lower notch/peak frequency comes from self inductance of both coils, and the higher notch/peak is due to the leakage inductance defined in Eq. 10.

The input return loss bandwidth BWS11 (S11=−10 dB) can be calculated as:

$${BW}_{S 11} = \frac{1 + \sqrt{3}}{2} \frac{{f}_{0}}{{Q}_{0}} \qquad ( 16 )$$

This bandwidth is only related to the resonated frequency f0 and the quality factor Q0 with the load R1, it does not relates to the ratio ‘n’ of the two coils and mutual coupling factor ‘k’. The 3 dB bandwidth BW3 dB can also be estimated to be:

$${BW}_{3 dB} = \sqrt{3} \frac{1 + \sqrt{3}}{2} \frac{{f}_{0}}{{Q}_{0}} = \sqrt{3} {BW}_{S 11} \qquad ( 17 )$$

Base on above analysis, the design method can be given for a wideband XFMR design or a wideband power amplifier with the wideband XFMR.

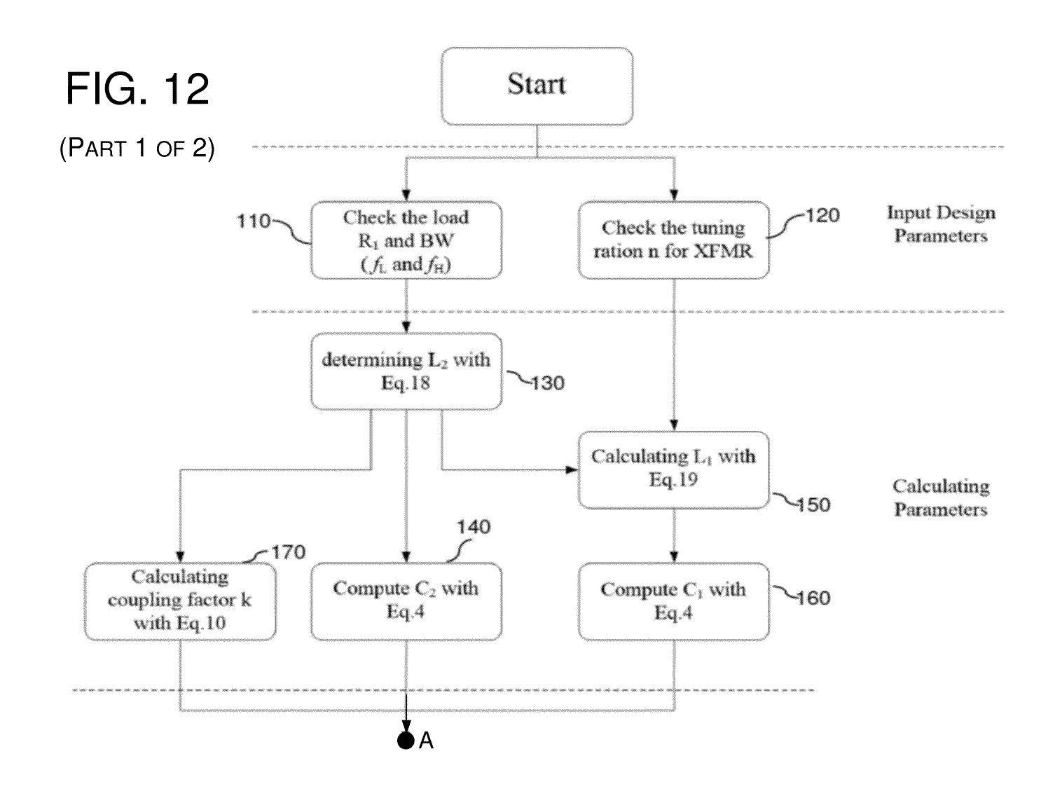

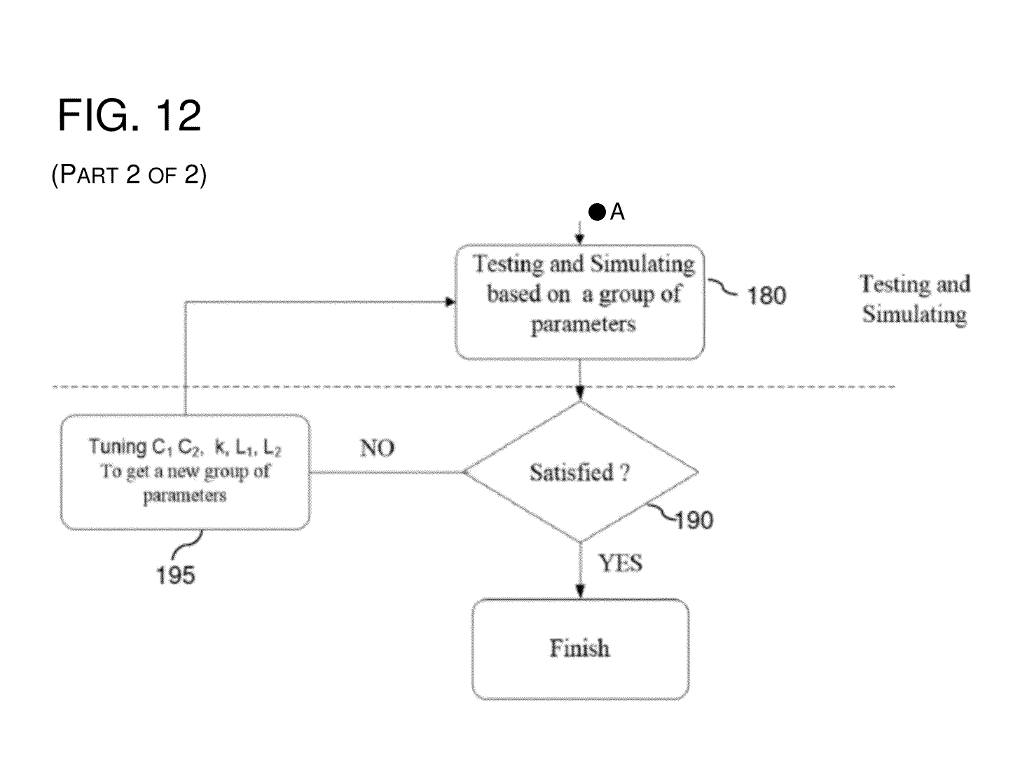

FIG. 12 is a schematic flow diagram showing a method for designing an ultra-wideband XFMR according to one embodiment of the present disclosure.

At 110, a designed bandwidth BW with a lower working frequency fL and a higher working frequency fH, and a designed load R1 are inputted.

At 120, an impedance transformation ratio n of the transformer is inputted, wherein:

$$n = \frac{{L}_{1}}{{L}_{2}} \qquad ( 19 )$$

At 130, using Eq. 16 or Eq. 17, the self inductance of the secondary coil L2 can be determined if a self-resonated frequency f0 of the secondary coil is firstly be assumed to be fL/sqrt(2).

$${L}_{2} >> \frac{{f}_{H} - {f}_{L}}{1 + \sqrt{3}} \frac{{R}_{1}}{2 {pf}_{L}^{2}} \qquad ( 18 )$$

At 140, a capacitance C2 of the secondary tuning capacitor C2 can also be determined using Eq. 4.

At 150 and 160, with Eq. 19, the self-inductance L1 of the primary coil L1 can be derived and its tuning capacitor C1 can be also derived with Eq. 4.

At 170, the current mutual coupling factor k is determined with Eq. 10 provided that the higher working frequency fH is equal or close to a higher resonated frequency f2.

At a result, a group of configuration parameters is determined, wherein the group of configuration parameters comprises the self-inductance of the primary coil L1, the self-inductance of the secondary coil L2, the mutual coupling factor k, the capacitance value of the primary tuning capacitor C1 and the capacitance value of the secondary tuning capacitor C2. At 180, the transformer configured with the determined group of configuration parameters is simulated or test to get frequency response characteristic thereof.

At 190, whether the frequency response characteristic of the transformer is satisfied a design requirement is determined. If YES, the design method is end; otherwise, the design method goes to 195 to tune the C1, C2, k, L1, or/and L2 to get another group of configuration parameters, and returns to 180. At 180, the transformer configured with the new determined group of configuration parameters is simulated or test until the frequency response characteristic meet the design requirement.

Because of parasitic and quality factor of primary and secondary coils, tuning the capacitors C1 and C2 are necessary, and tuning the capacitors is much easier in realization, especially for on-chip XFMR design. In one embodiment, the capacitors C1 and C2 are tuned preferably, the mutual coupling factor k is tuned secondarily, and the inductor L1 and L2 are tuned finally.

In operation, the resonated frequency f1 and f2 are not precise, so if a final design can't meet the requirement, then modifications can be made with the disclosed method. Because the coupling factor k can't be derived easily at one time, re-design with this flow is always needed.

This design procedure can be integrated in a commercial CAD tool for synthesizing a wideband XFMR with an exemplary and non-limiting algorithm shown in FIG. 12.

This bandwidth extension technique introducing leakage inductance can greatly relieve the requirement for a high coupling factor k, instead of a moderate coupling factor k, and it is much easier for the designer to implement such a XFMR on chip.

This bandwidth extension technique with leakage inductance incorporation can be used in amplifier design, such as LNAs, buffers, mixers, PAs, power detectors, but also valid for passive circuits, such as band-pass filters, power splitters, power combiners, couplers.

Furthermore, in the present disclosure, a relative bandwidth fBW of the ultra-wideband power amplifier with the impedance matching circuit as shown in FIG. 5 is higher than or equal to 50%, wherein fBW=(fH−fL)/fC, fC=(fH+fL)/2, fL is a minimum working frequency of the ultra-wideband power amplifier with the transformer shown in FIG. 5, and fH is a maximum working frequency of the ultra-wideband power amplifier.

Above all, by configuring appropriate parameters, the impedance matching circuit may obtain two pairs of conjugate poles. When the mutual coupling factor k is set to a proper value, the two pairs of conjugate poles tend to approach each other, and the entire impedance characteristic may substantially approximate to a characteristic of a Chebyshev band-pass filter, thereby implementing the impedance matching of an ultra-wideband signal.

Further, the impedance matching circuit of the present disclosure is not only suitable for a single-stage amplifier, but also suitable for a multi-stage amplifier solution.

The present disclosure is not limited to a coil implementation manner, yet needs to take feeding manner, area and other factors of the amplifier into account; in an optimization process, if the area takes a second place, the self-inductance value of the coil may be considered to be increased together with an increase in a mutual coupling factor, thereby obtaining higher bandwidth; and if the area is a dominant factor, vice versa. However, the self-inductance Q value needs to be prevented from being too small in the two cases; otherwise, the insertion loss and the impedance conversion characteristic may be affected seriously.

The present disclosure is not only applicable to radio frequency, but also applicable to the broadband amplifiers of microwave and millimeter bands. The present disclosure is not only suitable for a chip level, but also available for the broadband design of a PCB board level and a packaging level.

In the present disclosure, if the tuning capacitors C1 and C2 are changed into switchable capacitors, the wideband amplifier may be converted into the wideband tunable amplifier. In a micro-electromechanical system (MEMS), if the relative positions of two coils are adjustable and the tuning capacitors are tunable, a broadband amplifier system with tunable bandwidth may be implemented.

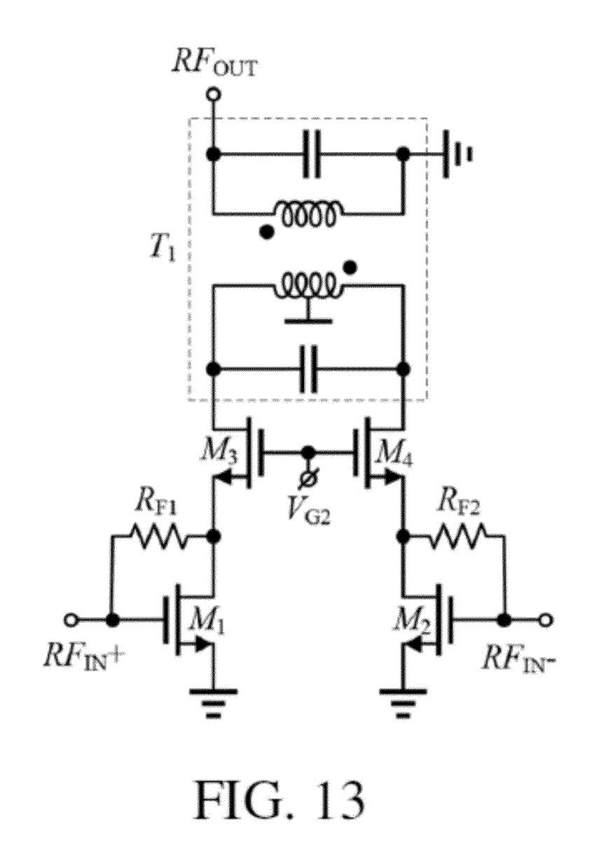

FIG. 13 is a circuit diagram showing a non-limiting self-biased differential to single-ended wideband buffer, with resistance feedback, according to one embodiment of the present disclosure. This buffer can perform input signal RFIN to current over a wideband frequency without any extra bias current or voltage for M1 and M2. T1 is the transformer with disclosed bandwidth extension technique shown in FIG. 5. Thus the whole circuit in FIG. 13 is wideband both for input and output. It can be used for driver amplifiers (DAs) or LO buffers with ultra low phase noise because of self-biased with resistors.

This bandwidth extension technique with leakage inductance incorporation is valid for different types of circuit topology, including single-to-differential type, differential-to-single type, differential-to-differential type, single-to-single type.

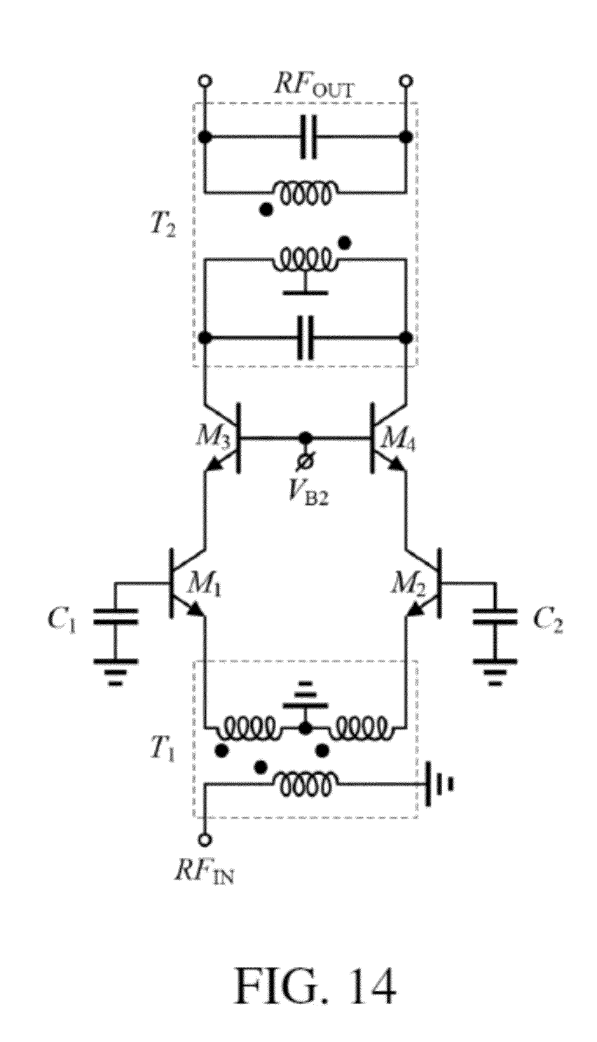

FIG. 14 is a circuit diagram showing a non-limiting common-base (CB or common gate: CG) wideband amplifier based wideband input transformer (XFMR) T1 and output wideband transformer XFMR T2 according to one embodiment of the present disclosure. In this configuration, input XFMR is used for single to differential conversion, and the secondary coil of T1 provides a DC path to ground. In this configuration, the tuning capacitors for primary and secondary coils can be removed, because part of the capacitance may be from the parasitic capacitance when the self inductance is large enough. In this case, the capacitors can be omitted, this is also valid for output XFMR T2. Because the common base amplifier are wideband, so from input, voltage-current conversion (Gm), to output port, all the parts are wideband, this configuration can be used for wideband applications. A common emitter (CE) or common source (CS) configuration can also be applied on chip similarly.

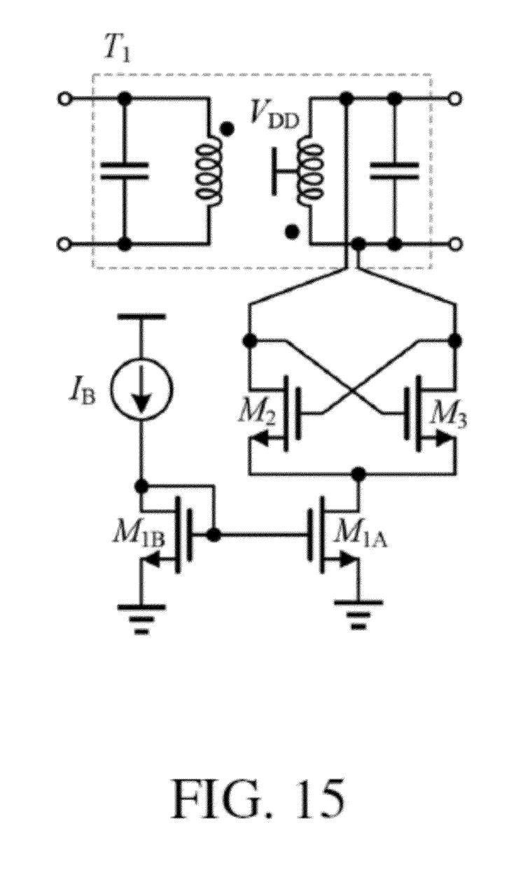

FIG. 15 is a circuit diagram showing a non-limiting band-pass filter (BPF) with quality factor enhanced circuit according to one embodiment of the present disclosure. A XFMR with both primary and secondary coil capacitance resonating can be used for wideband applications. However, for real implementation, the quality factor of self-inductance plays a very important role on the performance of XFMR over the wideband frequency. In some CMOS or SiGe RF technologies, only one thick metal is provided, so one side of XFMR may suffer from low quality problem, if a negative resistance compensation technique is introduced in FIG. 8, and the bias current can be easily trimmed for tuning the quality factor. With help of the auxiliary Q-enhanced circuit, this band-pass filter can be applied for the process without dual thick metal, and with both Q-enhanced technique for the two sides, this circuit can be applied for digital process without any thick metal. This Q-enhanced combined technology can also be used for active circuits, LNAs, PAs, buffers, mixers, and other circuits mentioned above.

The bandwidth of disclosed wideband XFMR can be trimmed in two ways.

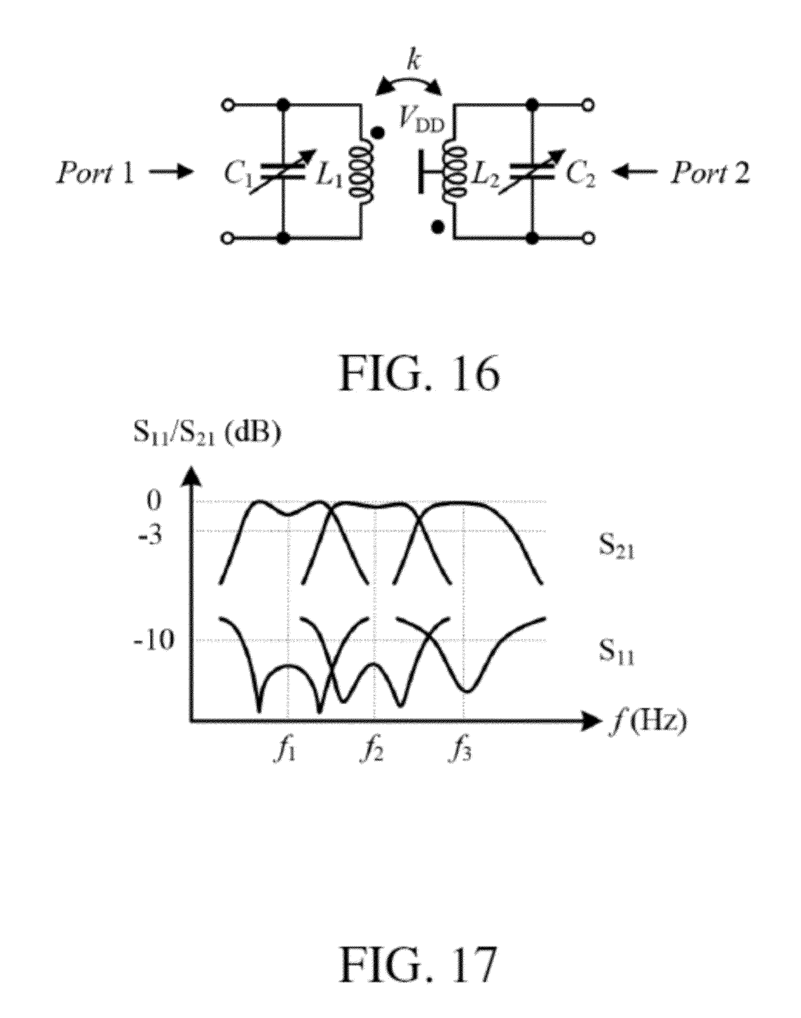

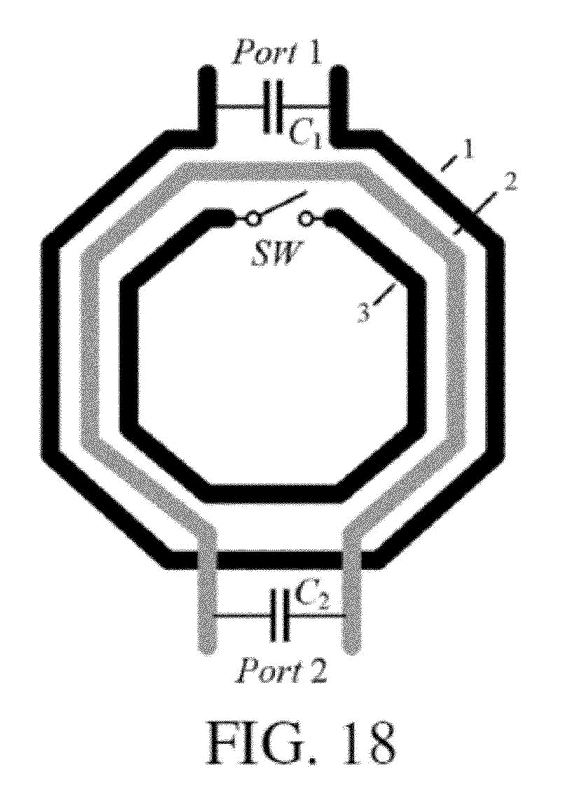

The first method is tuning the capacitance for primary and secondary sides. FIG. 16 is a circuit diagram showing a wideband XFMR with switchable capacitors according to one embodiment of the present disclosure. When switching the capacitors of C1 and C2, the resonating frequencies should be matched for primary and secondary coils. FIG. 17 is a diagram showing bandwidth shifting with frequency when trimming the resonating capacitors.

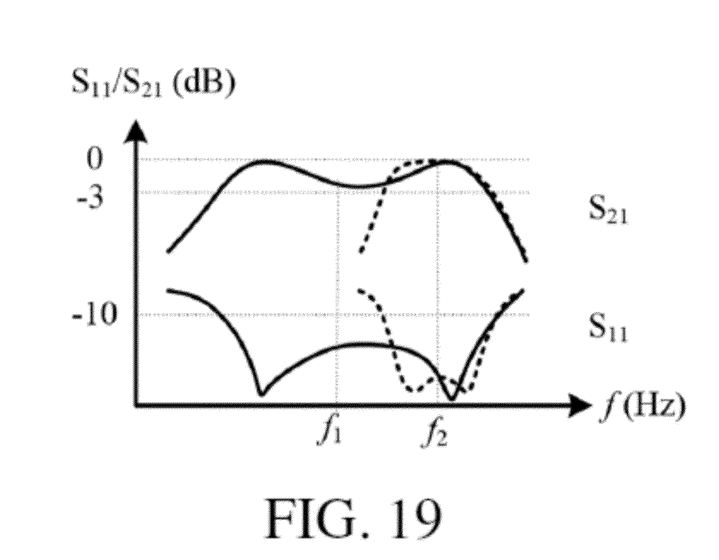

Another way to change the bandwidth of a wideband XFMR is to tune the coupling factor k. FIG. 18 shows a non-limiting tunable wideband XFMR according to one embodiment of the present disclosure. Part of magnetic flux can pass coil-3, if this coil is closed by switching on a coil switch SW, this part flux will introduce current in this coil from stimulus source, from Faraday's magnetic field induction law, the induced current will lower the flux passing through coil-3, this also change the magnetic flux passing through coil-2 when coil-2 and coil-3 are put closely. Thus the mutual coupling factor k between coil-1 and coil-2 will be changed accordingly. In this way, trimming the bandwidth of the wideband XFMR by tuning coupling factor k is implemented. FIG. 19 shows the results of S11 and S21 when the coil switch in FIG. 18 is ON (dashed line) and OFF (solid line). As can be seen, when the coil switch is switched ON (the k is lowered), the bandwidth is greatly reduced, to lower the insertion loss when the coil switch is ON, the size of this switch should be kept large to avoid energy loss in this coil, and the coupling factor between coil-1 and coil-3 should be carefully chosen, this can be easily achieved with 3D EM simulations.

It should also be mentioned that multi-coil can be applied in FIG. 18 for more options of trimming k factor, and mutual switching between these additional coils will produce more k factor choices, thus wideband XFMR can offer more bandwidth options.

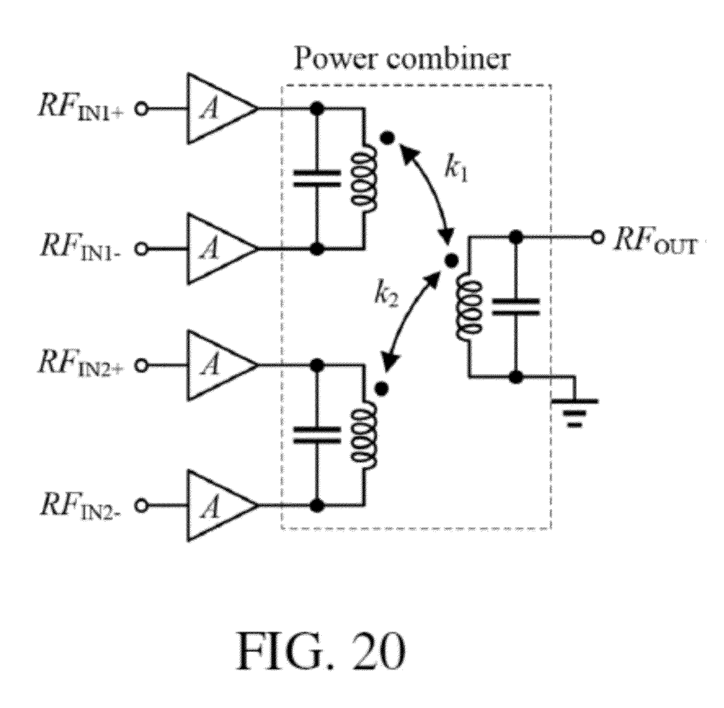

Wideband XFMR using disclosed bandwidth extension technique is also applicable for power combiner widely used in modern CMOS RF/MM PAs. FIG. 20 shows an exemplary and non-limiting schematic of 4-way voltage power combiner with wideband XFMR according to one embodiment of the present disclosure. And the bandwidth extension method is also similar with a normal wideband XFMR. For more ways combination, this technique still holds. Besides, this technique is also valid for power splitter.

The present disclosure has been described in sufficient details with a certain degree of particularity. It is understood to those skilled in the art that the present disclosure of embodiments has been made by way of examples only and that numerous changes in the arrangement and combination of parts may be resorted without departing from the spirit and scope of the present disclosure as claimed. Accordingly, the scope of the present disclosure is defined by the appended claims rather than the foregoing description of embodiments.

What is claimed is:

1. An ultra-wideband power amplifier, comprising:
a power amplifier unit configured to amplify a radio frequency input signal; and
an ultra-wideband impedance matching circuit coupled to an output terminal and/or an input terminal of the power amplifier unit and comprising a primary coil, a secondary coil mutual coupling with the primary coil, a primary tuning capacitor coupled with the primary coil in parallel and a secondary tuning capacitor coupled with the secondary coil in parallel,
wherein by means of setting a self-inductance of the primary coil, a self-inductance of the secondary coil, a mutual coupling factor between the primary coil and the secondary coil, a capacitance value of the primary tuning capacitor, and a capacitance value of the secondary tuning capacitor, a 3 dB bandwidth of the impedance matching circuit covers a first mutual resonated frequency and a second mutual resonated frequency formed by the impedance matching circuit.

2. The ultra-wideband power amplifier according to claim 1, wherein the setting a self-inductance of the primary coil, a self-inductance of the secondary coil, a mutual coupling factor between the primary coil and the secondary coil, a capacitance value of the primary tuning capacitor, and a capacitance value of the secondary tuning capacitor comprises:
setting a load R₁, a desired bandwidth with a lower working frequency f_{L} and a higher working frequency f_{H}, an impedance transformation ratio n of the impedance matching circuit;
calculating a self inductance of the secondary coil L₂ according to:
$${L}_{2} >> \frac{{f}_{H} - {f}_{L}}{1 + \sqrt{3}} \frac{{R}_{1}}{2 {pf}_{L}^{2}} ;$$
calculating a capacitance of the secondary tuning capacitor C₂ according to:
$${f}_{0} = \frac{1}{2 p \sqrt{{L}_{1} {C}_{1}}} = \frac{1}{2 p \sqrt{{L}_{2} {C}_{2}}} , \\ and$$
$${f}_{0} >> \frac{{f}_{L}}{\sqrt{2}} ;$$
calculating a self inductance of the primary coil L₁ according to:
$$n = \frac{{L}_{1}}{{L}_{2}} ;$$
calculating a capacitance of the primary tuning capacitor C₁ according to:
$${f}_{0} = \frac{1}{2 p \sqrt{{L}_{1} {C}_{1}}} = \frac{1}{2 p \sqrt{{L}_{2} {C}_{2}}} , \\ and$$
$${f}_{0} >> \frac{{f}_{L}}{\sqrt{2}} ;$$
and
calculating a mutual coupling factor k between the primary coil L₁ and the secondary coil L₁ according to:
$${f}_{2} = \frac{1}{2 p \sqrt{1 - k}} {f}_{0} , \\ {f}_{0} >> \frac{{f}_{L}}{\sqrt{2}} , \\ {f}_{2} >> {f}_{H} .$$

3. The ultra-wideband power amplifier according to claim 1, wherein the primary tuning capacitor and the secondary tuning capacitor are tunable capacitors respectively.

4. The ultra-wideband power amplifier according to claim 1, wherein a relative bandwidth f_{BW} of the impedance matching circuit is higher than or equal to 50%, wherein f_{BW}=(f_{H}−f_{L})/f_{C}, f_{C}=(f_{H}+f_{L})/2, f_{L} is a minimum working frequency of the impedance matching circuit, and f_{H} is a maximum working frequency of the impedance matching circuit.

5. The ultra-wideband power amplifier according to claim 1, wherein the impedance matching circuit further comprises a third coil coupling with the primary coil and the secondary coil, and a coil switch coupled between two terminals of the third coil, and the coil switch is turned on/off to trim the mutual coupling factor between the primary coil and the secondary coil.

6. The ultra-wideband power amplifier according to claim 1, wherein the mutual coupling factor is smaller than 0.8.

7. A method for designing an ultra-wideband impedance matching circuit for an ultra-wideband power amplifier, the impedance matching circuit comprising a primary coil L₁, a secondary coil L₂ mutual coupling with the primary coil L₁, a primary tuning capacitor C₁ coupled with the primary coil in parallel and a secondary tuning capacitor C₂ coupled with the secondary coil in parallel, and having a first mutual resonated frequency f₁ and a second mutual resonated frequency f₂, the method comprising:
setting a load R₁, a desired bandwidth with a lower working frequency f_{L} and a higher working frequency f_{H}, an impedance transformation ratio n of the impedance matching circuit;
obtaining a group of configuration parameters according to the load R₁, the lower working frequency f_{L} and the higher working frequency f_{H,} the impedance transformation ratio n, wherein the group of configuration parameters comprises a self-inductance of the primary coil L₁, a self-inductance of the secondary coil L_{2,} a mutual coupling factor k, a capacitance of the primary tuning capacitor C₁ and a capacitance of the secondary tuning capacitor C₂;
providing a current temporary impedance matching circuit configured with the obtained group of configuration parameters;
testing the current temporary impedance matching circuit to get a frequency response characteristic of the current temporary impedance matching circuit;
determining whether or not the frequency response characteristic of the current temporary impedance matching circuit meets a design requirement;
regarding the current temporary impedance matching circuit as a final impedance matching circuit if the frequency response characteristic of the current temporary impedance matching circuit meets the design requirement; and
tuning one or more of the self-inductance of the primary coil L₁, the self-inductance of the secondary coil L₂, the mutual coupling factor k, the capacitance of the primary tuning capacitor C₁ and the capacitance of the secondary tuning capacitor C₂ to obtain a new group of configuration parameters to proceed if the frequency response characteristic of the temporary impedance matching circuit doesn't meet the design requirement.

8. The method according to claim 7, wherein the obtaining the group of configuration parameters according to the load R₁, the lower working frequency F_{L} and the higher working frequency f_{H}, the impedance transformation ratio n comprises:
calculating a self inductance of the secondary coil L₂ according to:
$${L}_{2} >> \frac{{f}_{H} - {f}_{L}}{1 + \sqrt{3}} \frac{{R}_{1}}{2 {pf}_{L}^{2}} ;$$
calculating a capacitance of the secondary tuning capacitor C₂ according to:
$${f}_{0} = \frac{1}{2 p \sqrt{{L}_{1} {C}_{1}}} = \frac{1}{2 p \sqrt{{L}_{2} {C}_{2}}} , \\ and$$
$${f}_{0} >> \frac{{f}_{L}}{\sqrt{2}} ;$$
calculating a self inductance of the primary coil L₁ according to:
$$n = \frac{{L}_{1}}{{L}_{2}} ;$$
calculating a capacitance of the primary tuning capacitor C₁ according to:
$${f}_{0} = \frac{1}{2 p \sqrt{{L}_{1} {C}_{1}}} = \frac{1}{2 p \sqrt{{L}_{2} {C}_{2}}} , \\ and$$
$${f}_{0} >> \frac{{f}_{L}}{\sqrt{2}} ;$$
and
calculating a mutual coupling factor k between the primary coil L₁ and the secondary coil L₁ according to:
$${f}_{2} = \frac{1}{2 p \sqrt{1 - k}} {f}_{0} , \\ {f}_{0} >> \frac{{f}_{L}}{\sqrt{2}} , \\ {f}_{2} >> {f}_{H} .$$

9. The method according to claim 7, wherein the design requirement at least comprises a 3 dB bandwidth of the impedance matching circuit covers the first mutual resonated frequency f₁ and the second mutual resonated frequency f₂.

10. The method according to claim 7, wherein the design requirement at least comprises that a relative bandwidth f_{BW} of the impedance matching circuit is higher than or equal to 50%, and wherein f_{BW}=(f_{H}−f_{L})/f_{C}, f_{C}=(f_{H}+f_{L})/2.

11. The method according to claim 7, wherein the primary tuning capacitor and the secondary tuning capacitor are tunable capacitors.

12. The method according to claim 7, wherein the impedance matching circuit further comprises a third coil coupling with the primary coil and the secondary coil, and a coil switch coupled between two terminals of the third coil, and the coil switch is turned on/off to trim the mutual coupling factor between the primary coil and the secondary coil.

13. The method according to claim 7, wherein, wherein the mutual coupling factor is smaller than 0.8.
